(19) United States
(12) Patent Application Publication
(10) Pub. No.: US 2015/0270203 A1
(43) Pub. Date: Sep. 24, 2015

(54) SEMICONDUCTOR DEVICE AND METHOD OF FABRICATING THE SAME

(71) Applicant: Kabushiki Kaisha Toshiba, Minato-ku (JP)

(72) Inventors: Hideo NISHIUCHI, Yokohama (JP); Takashi TOGASAKI, Yokohama (JP); Takayuki TAJIMA, Sagamihara (JP)

(73) Assignee: Kabushiki Kaisha Toshiba, Minato-ku (JP)

(21) Appl. No.: 14/635,070

(22) Filed: Mar. 2, 2015

(30) Foreign Application Priority Data
Mar. 18, 2014 (JP) 2014-055666

(51) Int. Cl. H01L 23/495; H01L 21/48

(52) U.S. Cl. CPC H01L 23/49568; H01L 23/49551; H01L 23/49575; H01L 23/49582; H01L 21/4825; H01L 21/4842; H01L 21/4803; H01L 23/49517

(57) ABSTRACT

According to one embodiment, a first semiconductor element has a first electrode connected to the first conductor, a second electrode connected to the second conductor, and a control electrode connected to a first signal terminal. A second semiconductor element has a first electrode connected to the first conductor, and a second electrode connected to the second conductor. A third semiconductor element has a first electrode connected to the third conductor, a second electrode connected to the fourth conductor, and a control electrode connected to a second signal terminal. A fourth semiconductor element has a first electrode connected to the third conductor, and a second electrode connected to the fourth conductor.

### CROSS REFERENCE TO RELATED APPLICATION

This application is based upon and claims the benefit of priority from the prior Japanese Patent Application No. 2014-055666, filed on Mar. 18, 2014, the entire contents of which are incorporated herein by reference.

### FIELD

Embodiments described herein relate to a semiconductor device and a method of fabricating the same.

### BACKGROUND

Recently, hybrid vehicles using an internal combustion engine and a motor together have rapidly been widespread, for the purpose of improving fuel efficiency of an automobile. In addition, commercialization of electric vehicles which can travel solely by a motor has been advancing. In order to put these automobiles into practice, power converters which perform conversion from AC power to DC power, and conversion from AC power to DC power become necessary.

In hybrid vehicles and electric vehicles, miniaturization and high reliability of a power converter have been required. In order to achieve miniaturization and high reliability of a power converter, a semiconductor device (semiconductor module) with a high cooling efficiency becomes necessary. As the semiconductor device (semiconductor module), a power converter structure of a double-sided heat radiation type has been proposed, in which conductors are connected to front and back surfaces of a semiconductor element, and heats are radiated from the respective conductors to a cooler.

### BRIEF DESCRIPTION OF THE DRAWINGS

FIG. 1 is a circuit diagram showing a power converter according to a first embodiment;

FIG. 2 is a wiring diagram of the power converter composed using semiconductor modules as semiconductor devices according to the first embodiment;

FIG. 3 is a sectional view showing the semiconductor module as the semiconductor device according to the first embodiment when loaded on a cooler;

FIG. 4 is an exploded perspective view showing constituent components of the semiconductor module according to the first embodiment;

FIG. 5 is a perspective view showing the semiconductor module according to the first embodiment;

FIG. 6 is a perspective view showing the semiconductor module according to the first embodiment;

FIG. 7 is a sectional view showing the semiconductor module according to the first embodiment;

FIG. 8 is a front view showing an internal structure of the semiconductor module according to the first embodiment when seen through the mold resin;

FIG. 9 is a perspective view showing the internal structure of the semiconductor module according to the first embodiment when seen through the mold resin;

FIG. 10 is a perspective view showing the internal structure of the semiconductor module according to the first embodiment when seen through the mold resin;

FIG. 11 is a plan view showing the semiconductor module according to the first embodiment;

FIG. 12 is a front view showing the semiconductor module according to the first embodiment;

FIG. 13 is a side view showing the semiconductor module according to the first embodiment;

FIG. 14 is a perspective view showing a lead frame used in the semiconductor module according to the first embodiment;

FIG. 15 is a sectional view showing a semiconductor module as a semiconductor device according to a second embodiment;

FIG. 16 is a perspective view showing a semiconductor module as a semiconductor device according to a third embodiment;

FIG. 17 is a view showing a connection example of the semiconductor modules according to the third embodiment; and

FIG. 18A-FIG. 18F are views for explaining a method of fabricating a semiconductor module as a semiconductor device according to a fourth embodiment.

### DETAILED DESCRIPTION

According to one embodiment, a semiconductor device includes first to fourth semiconductor elements, and first to third power terminals. The first semiconductor element is provided between a first conductor and a second conductor, has a first electrode connected to the first conductor, a second electrode connected to the second conductor, and a control electrode connected to a first signal terminal. The second semiconductor element is provided between the first conductor and the second conductor, has a first electrode connected to the first conductor, and a second electrode connected to the second conductor. the third semiconductor element is provided between a third conductor and a fourth conductor, has a first electrode connected to the third conductor, a second electrode connected to the fourth conductor, and a control electrode connected to a second signal terminal. The fourth semiconductor element is provided between the third conductor and the fourth conductor, has a first electrode connected to the third conductor, and a second electrode connected to the fourth conductor. The first power terminal has one end connected to the second conductor and the other end extending more outward than the second conductor. The second power terminal connects the first conductor and the fourth conductor and extends more outward than the first conductor and the fourth conductor. The third power terminal has one end connected to the third conductor and the other end extending more outward than the third conductor.

Hereinafter, a plurality of further embodiments will be described with reference to the drawings. In the drawings, the same symbols show the same or similar portions. In addition, the respective drawings are schematic views of embodiments, and are for urging the embodiments to be understood, and there are portions in an actual device which are different in the shapes, dimensions, and ratios thereof. But the design of these may appropriately be changed in consideration of the following description and the prior art.

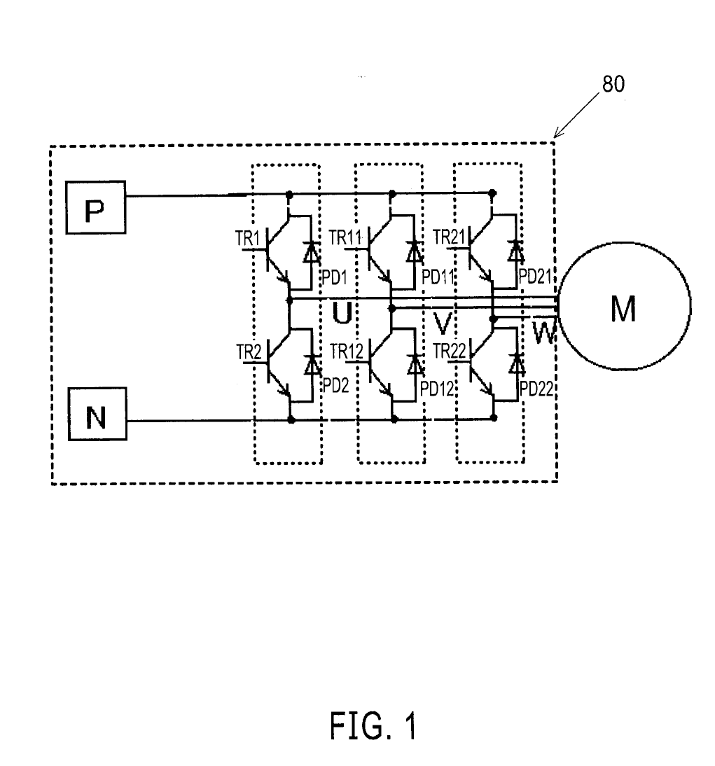

A semiconductor device according to a first embodiment will be described with reference to the drawings. FIG. 1 is a circuit diagram showing a power converter.

As shown in FIG. 1, a power converter 80 includes a battery P, a battery N, a transistor TR1, a transistor TR2, a transistor TR11, a transistor TR12, a transistor TR21, a transistor TR22, a protection diode PD1, a protection diode PD2, a protection diode PD11, a protection diode PD12, a protection diode PD21, a protection diode PD22. The battery P and the battery N are each a DC power source. The battery P is a high potential side power source, and the battery N is a low potential side power source.

The power converter 80 is a circuit to drive a motor M of three-phase AC (U-phase, V-phase, W-phase) from the DC power source. In the power converter 80, in the U-phase, the transistor TR1, the transistor TR2, the protection diode PD1, the protection diode PD2 are provided. In the V-phase, the transistor TR11, the transistor TR12, the protection diode PD11, the protection diode PD12 are provided. In the W-phase, the transistor TR21, the transistor TR22, the protection diode PD21, the protection diode PD22 are provided. As the transistor TR1, the transistor TR2, the transistor TR11, the transistor TR12, the transistor TR21, and the transistor TR22, an IGBT (insulated gate bipolar transistor) is used, for example.

In the U-phase, the transistor TR1 and the transistor TR2 which are connected in series are provided between the battery P and the battery N. The protection diode PD1 has a cathode connected to a collector of the transistor TR1, and an anode connected to an emitter of the transistor TR1. The protection diode PD2 has a cathode connected to a collector of the transistor TR2, and an anode connected to an emitter of the transistor TR2. In the U-phase, based on a control signal inputted to a gate of the transistor TR1 and a control signal inputted to a gate of the transistor TR2, a U-phase output signal is outputted from between the emitter of the transistor TR1 and the collector of the transistor TR2, and the U-phase output signal is inputted to the motor M.

In the V-phase, the transistor TR11 and the transistor TR12 which are connected in series are provided between the battery P and the battery N. The protection diode PD11 has a cathode connected to a collector of the transistor TR11, and an anode connected to an emitter of the transistor

TR11. The protection diode PD12 has a cathode connected to a collector of the transistor TR12, and an anode connected to an emitter of the transistor TR12. In the V-phase, based on a control signal inputted to a gate of the transistor TR11 and a control signal inputted to a gate of the transistor TR12, a V-phase output signal is outputted from between the emitter of the transistor TR11 and the collector of the transistor TR12, and the V-phase output signal is inputted to the motor M.

In the W-phase, the transistor TR21 and the transistor TR22 which are connected in series are provided between the battery P and the battery N. The protection diode PD21 has a cathode connected to a collector of the transistor TR21, and an anode connected to an emitter of the transistor TR21. The protection diode PD22 has a cathode connected to a collector of the transistor TR22, and an anode connected to an emitter of the transistor TR22. In the W-phase, based on a control signal inputted to a gate of the transistor TR21 and a control signal inputted to a gate of the transistor TR22, a W-phase output signal is outputted from between the emitter of the transistor TR21 and the collector of the transistor TR22, and the W-phase output signal is inputted to the motor M.

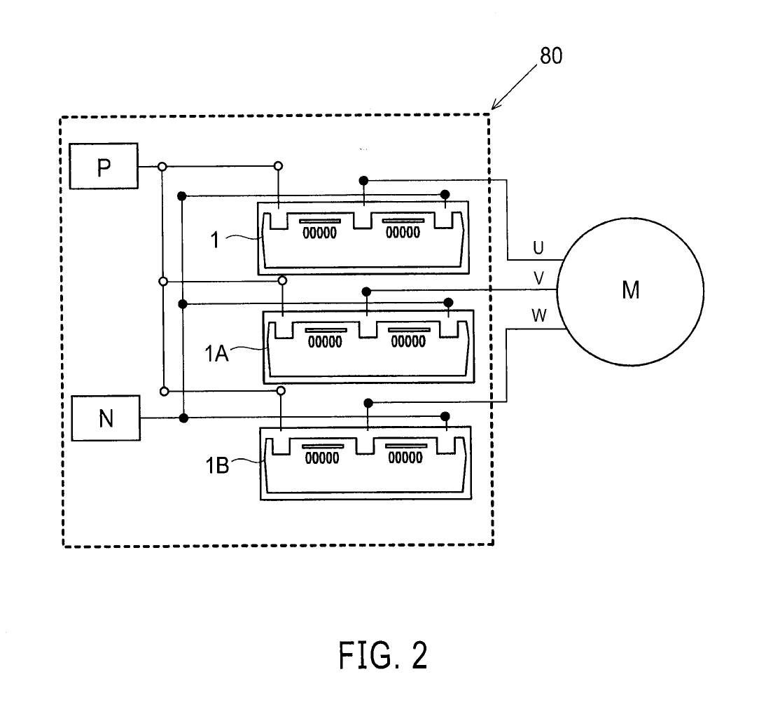

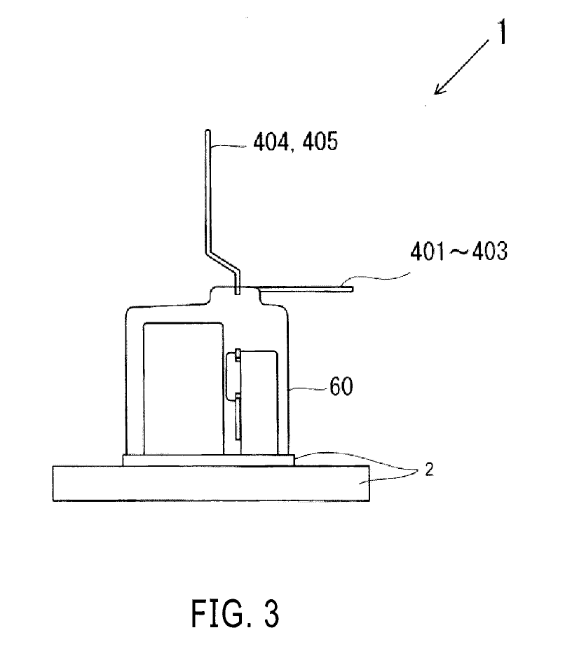

A semiconductor module as a semiconductor device will be described with reference to the drawings. FIG. 2 is a wiring diagram of a power converter composed using semiconductor modules as the semiconductor device. FIG. 3 is a sectional view of a semiconductor module when provided on a cooler.

As shown in FIG. 2, the power converter 80 includes a semiconductor module 1, a semiconductor module 1A, and a semiconductor module 1B. The semiconductor module 1 outputs the U-phase output signal to the motor M. The semiconductor module 1A outputs the V-phase output signal to the motor M. The semiconductor module 1B outputs the W-phase output signal to the motor M. The semiconductor module 1, the semiconductor module 1A, and the semiconductor module 1B have the same configuration and structure. For the reason, hereinafter, the specific configuration will be described using the semiconductor module 1 as an example.

As shown in FIG. 3, one side surface of the semiconductor module 1 directly contacts with a cooler 2, and heat generated in the semiconductor module 1 is radiated by the cooler 2. The semiconductor module 1 has a mold resin 60, a signal electrode 4, and a power terminal 5. The mold resin 60 is made of an insulator. The semiconductor module 1 is sealed with the mold resin 60, except the side surface contacting the cooler 2. The signal terminals 404 ,405 respectively have one end (base end portion) sealed with the mold resin 60, and the other end extending more outward than the mold resin 60. The signal terminals 404, 405 are respectively electrically connected to control boards not shown, and control a flow of electricity of the semiconductor device 1. The power terminals 401-403 respectively have one end (base end portion) sealed with the mold resin 60, and the other end extending more outward than the mold resin 60. The power terminals 401-403 respectively have a first power terminal is connected to the battery P, a second power terminal outputs the output signal of the semiconductor module 1 to the motor M, and the third power terminal is connected to the battery N.

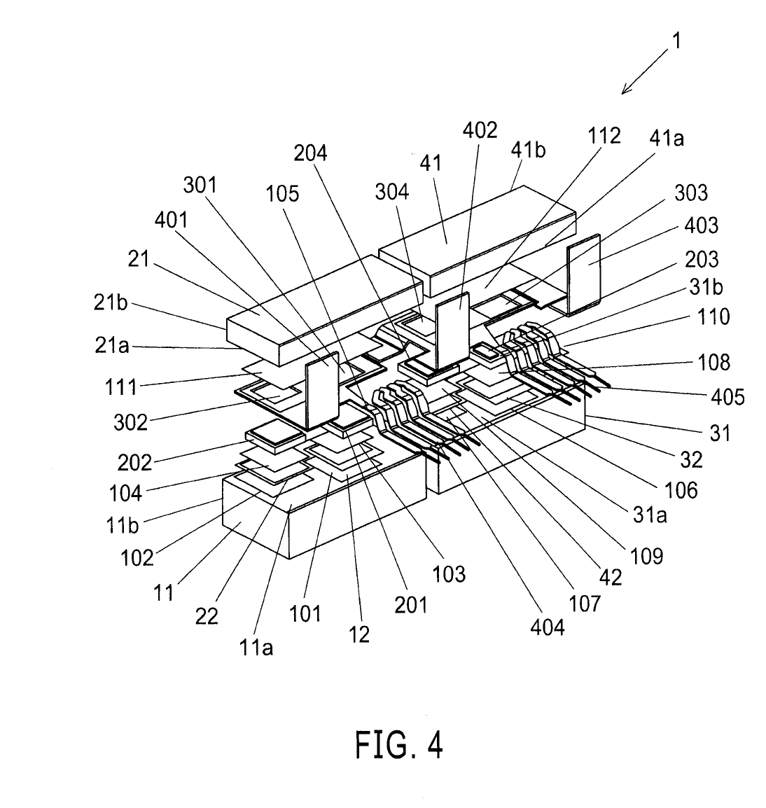

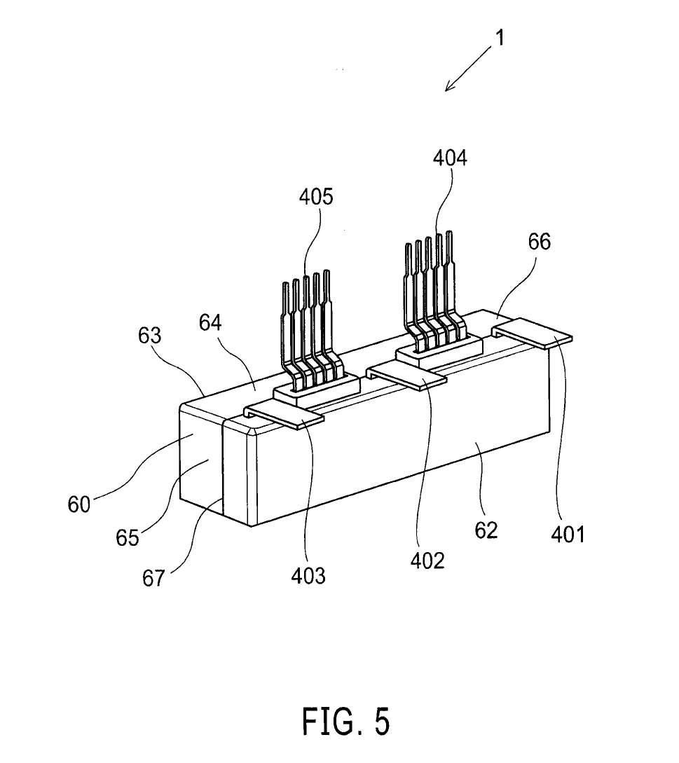

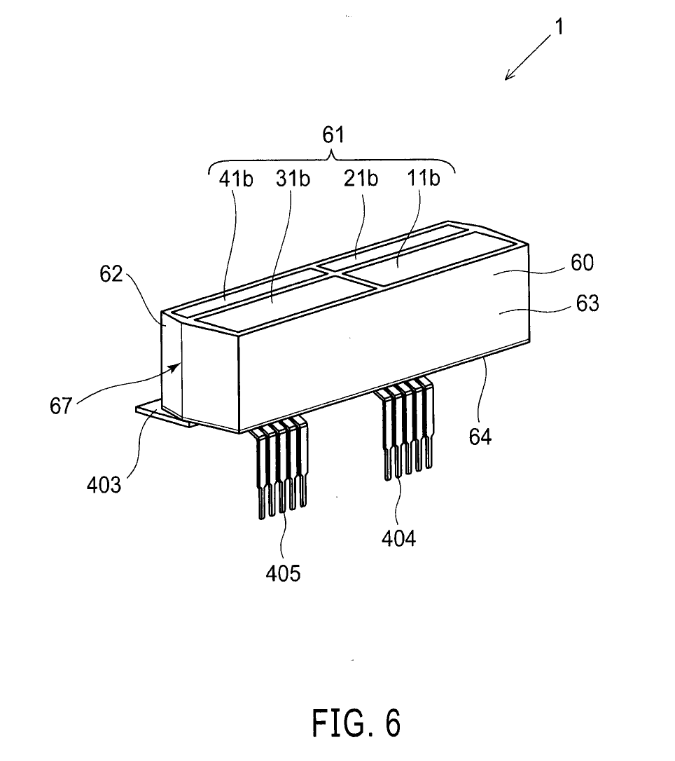

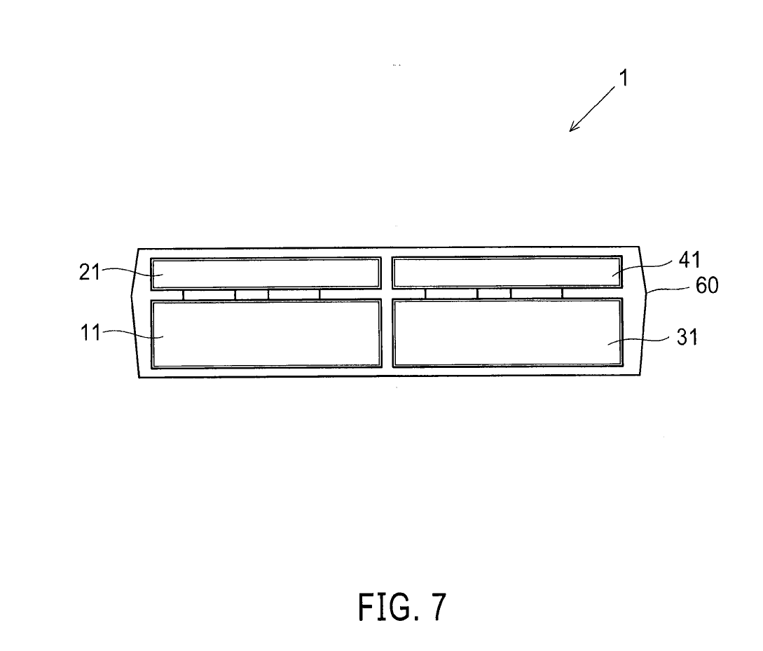

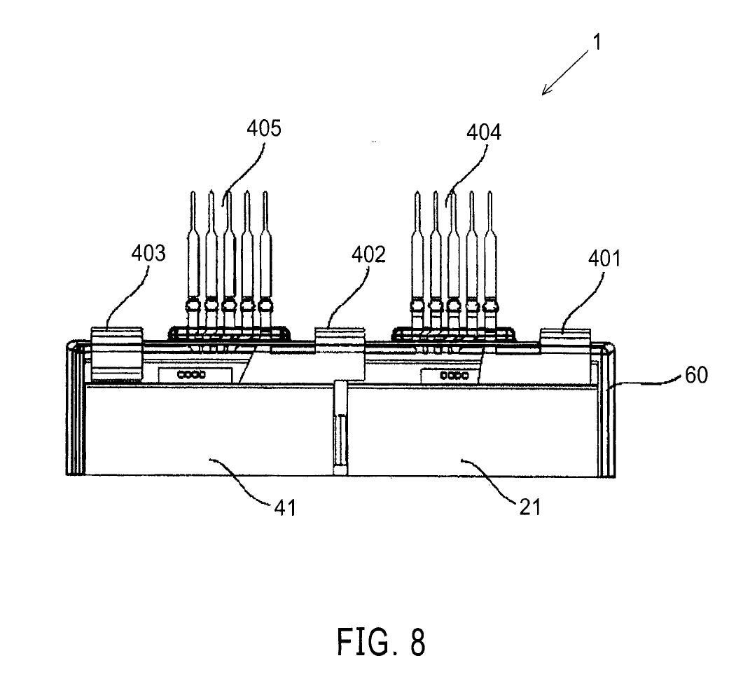

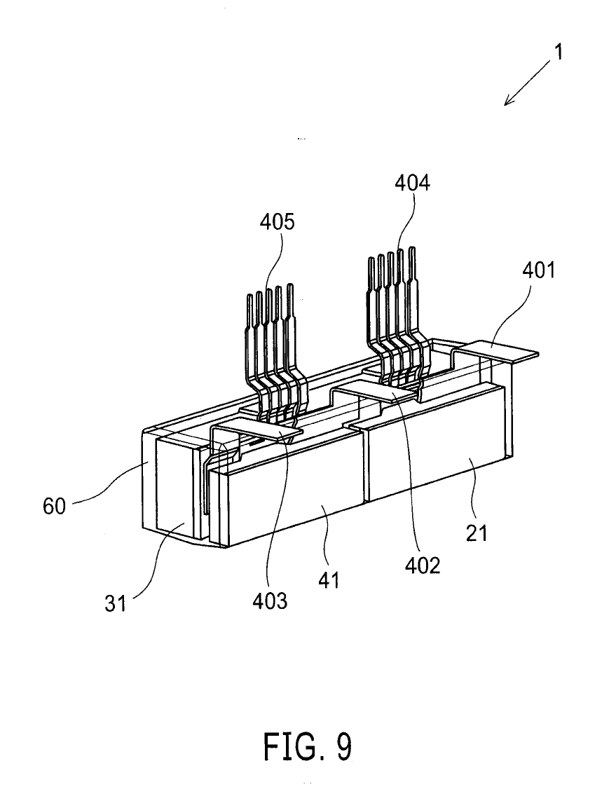

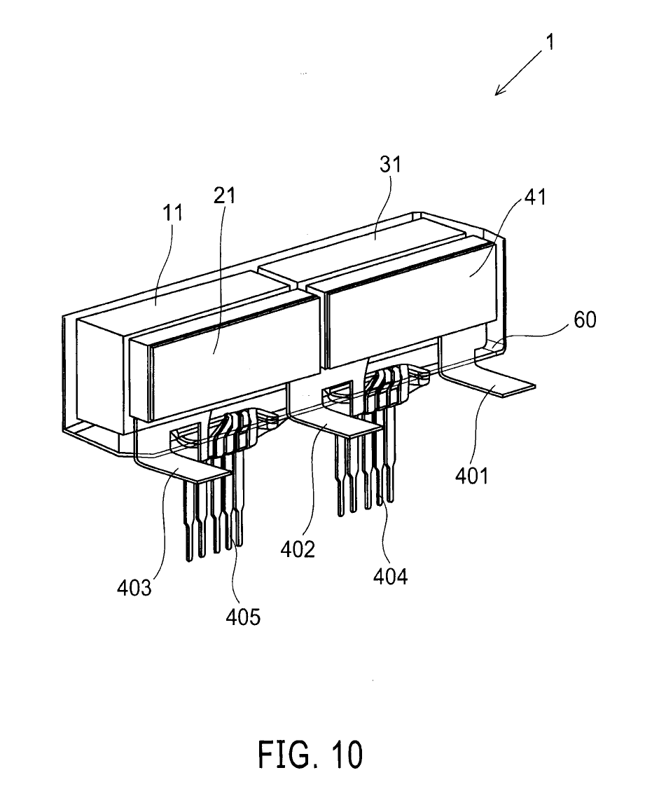

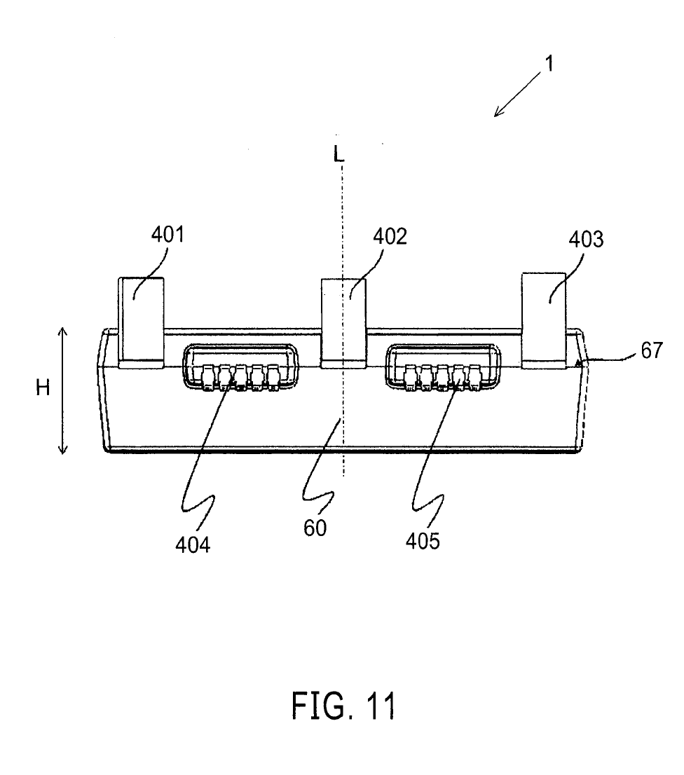

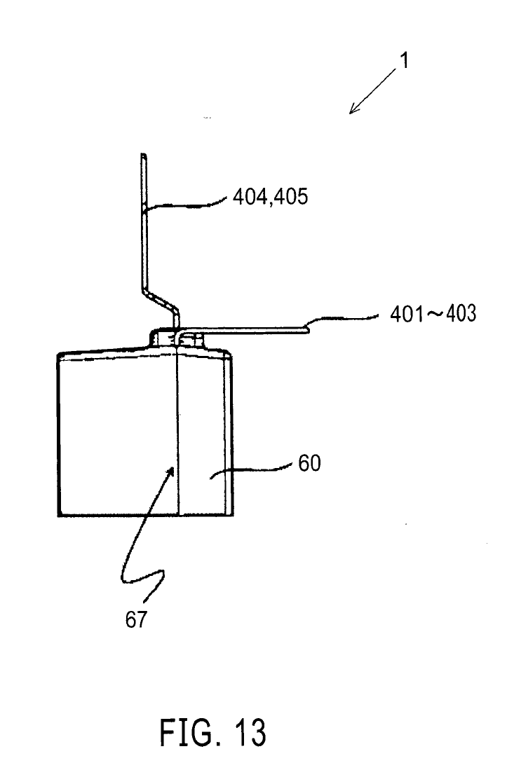

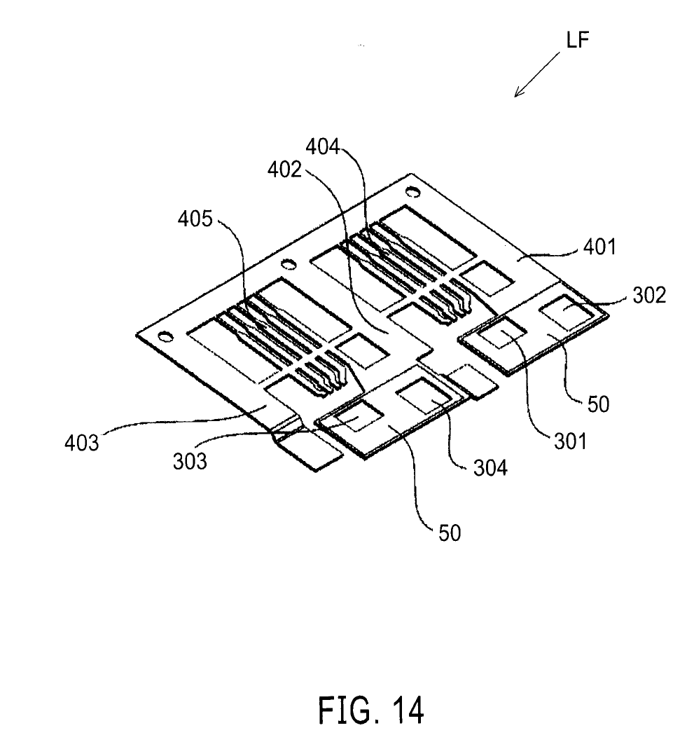

A specific configuration of the semiconductor module as the semiconductor device will be described with reference to the drawings. FIG. 4 is an exploded perspective view showing constituent components of the semiconductor module. FIG. 5 and FIG. 6 are each a perspective view showing the semiconductor module. FIG. 7 is a sectional view showing the semiconductor module. FIG. 8 is a front view showing an internal structure of the semiconductor module when seen through the mold resin. FIG. 9 is a perspective view showing the internal structure of the semiconductor module when seen through the mold resin. FIG. 10 is a perspective view showing the internal structure of the semiconductor module when seen through the mold resin. FIG. 11 is a plan view showing the semiconductor module. Fig, 12 is a front view showing the semiconductor module. FIG. 13 is a side view showing the semiconductor module. FIG. 14 is a perspective view showing a lead frame used in the semiconductor module.

As shown in FIG. 4, the semiconductor module 1 is a semiconductor device of a double-sided heat radiation type and a vertical mounting type. In addition, the semiconductor module 1 shown in FIG. 13 is also a semiconductor device of a double-sided heat radiation type and a vertical mounting type

The semiconductor module 1 includes a conductor 11 (first conductor), a conductor 21 (second conductor), a conductor 31 (third conductor), a conductor 41 (fourth conductor), a semiconductor element 12 (first semiconductor element), a semiconductor element 22 (second semiconductor element), a semiconductor element 32 (third semiconductor element), a semiconductor element 42 (fourth semiconductor element), a power terminal 401 (first power terminal), a power terminal 402 (second power terminal), a power terminal 403 (third power terminal), a signal terminal 404 (first signal terminal), and a signal terminal 405 (second signal terminal). Here, the semiconductor element 12 corresponds to the transistor TR2 shown in FIG. 2. The semiconductor element 22 corresponds to the protection diode PD2 shown in FIG. 2. The semiconductor element 32 corresponds to the transistor TR1 shown in FIG. 2. The semiconductor element 42 corresponds to the protection diode PD1 shown in FIG. 2.

An IGBT is used as the semiconductor element 12 and the semiconductor element 32. The semiconductor element 22 is a protection diode to protect the semiconductor element 12 from the static electricity and excess voltage from outside. The semiconductor element 42 is a protection diode to protect the semiconductor element 32 from the static electricity and excess voltage from outside.

Each of the conductor 11, the conductor 21, the conductor 31, and the conductor 41 has a rectangular column shape. Copper (Cu) or copper alloy with low resistance and superior in radiation property is used for the conductor 11, the conductor 21, the conductor 31, and the conductor 41.

Each of the power terminal 401, the power terminal 402, the power terminal 403, the signal terminal 404, and the signal terminal 405 is composed of copper (Cu), for example, and the surface is subjected to metal plating (tin plating, for example)

The semiconductor element 12 is provided between the conductor 11 and the conductor 21, and has a collector electrically connected to the conductor 11, and an emitter electrically connected to the conductor 21. The semiconductor element 22 is provided between the conductor 11 and the conductor 21, and has a cathode electrically connected to the conductor 11, and an anode electrically connected to the conductor 21.

The semiconductor element 32 is provided between the conductor 31 and the conductor 41, and has a collector electrically connected to the conductor 31, and an emitter electrically connected to the conductor 41. The semiconductor element 42 is provided between the conductor 31 and the conductor 41, and has a cathode electrically connected to the conductor 31, and an anode electrically connected to the conductor 41.

The conductor 11 and the conductor 41 are electrically connected, and thereby the semiconductor module 1 functions as a semiconductor device of a U-phase which composes the power converter 80.

In the conductor 11, a main surface (side surface) composes a rectangular joint surface 11a (first joint surface), and a bottom surface (first bottom surface) 11b orthogonal to the joint surface 11a composes a radiating surface. Similarly in the conductor 21, a main surface (side surface) composes a rectangular joint surface 21a (second joint surface), and a bottom surface (second bottom surface) 21b orthogonal to the joint surface 21a composes a radiating surface. The conductor 21 is arranged such that the joint surface 21a faces the joint surface 11a of the conductor 11 in parallel, and the bottom surface 21b (second bottom surface) is on the same plane as the bottom surface 11b (first bottom surface) of the first conductor 11. In each of the conductors 11, 21, the joint surface and the bottom surface are formed so that they are orthogonal to each other, but without being limited to this, it they may be formed so as to cross with each other at a different angle other than a right angle.

In the conductor 31, a main surface (side surface) composes a rectangular joint surface 31a (third joint surface), and a bottom surface (first bottom surface) 31b orthogonal to the joint surface 31a composes a radiating surface. Similarly in the conductor 41, a main surface (side surface) composes a rectangular joint surface (fourth joint surface) 41a, and a bottom surface (fourth bottom surface) 41b orthogonal to the joint surface 41a composes a radiating surface. The conductor 41 is arranged such that the joint surface 41a faces the joint surface 31a of the conductor 31 in parallel, and the bottom surface 41b (fourth bottom surface) is on the same plane as the bottom surface 31b (third bottom surface) of the conductor 31. In each of the conductors 31, 41, the joint surface and the bottom surface are formed so that they are orthogonal to each other, but without being limited to this, they may be formed so as to cross with each other at a different angle other than a right angle.

Each of the semiconductor element 12 and the semiconductor element 32 has a rectangular plate shape, and a second electrode (emitter) and a control electrode (gate) are provided on the surface, and a first electrode (collector) is provided on a back surface. The surface of each of the semiconductor element 12 and the semiconductor element 32 is covered with an insulating film such as a polyimide film other than the second electrode and the control electrode.

Each of the semiconductor element 22 and the semiconductor element 42 has a rectangular plate shape, and a second electrode (anode) is provided on the surface, and a first electrode (cathode) is provided on a back surface. The surface of each of the semiconductor element 22 and the semiconductor element 42 is covered with an insulating film such as a polyimide film other than the second electrode.

The semiconductor element 12 is arranged in parallel with the joint surface 11a of the conductor 11, and the first electrode is jointed to the joint surface 11a of the conductor 11 with a connecting body 101 (first connecting body), such as a rectangular solder sheet. The semiconductor element 22 is arranged in parallel with the joint surface 11a of the conductor 11, and is arranged in parallel with the semiconductor element 12 in the longitudinal direction of the conductor 11. In the semiconductor element 22, the first electrode is jointed to the joint surface 11a of the conductor 11 with a connecting body 102 (second connecting body), such as a rectangular solder sheet.

The semiconductor element 12 and the semiconductor element 22 are arranged in parallel with the joint surface 11a of the conductor 11, and vertical to the bottom surface 11b of the conductor 11. A connecting body 105 (fifth connecting body) such as a rectangular solder sheet is provided on the joint surface 11a of the conductor 11, and is arranged side by side at the side of the semiconductor element 12.

A convex conductor 201 (first convex conductor) for positioning is jointed on the electrode of the surface of the semiconductor element 12, via a connecting body 103 (third connecting body) such as a rectangular solder sheet. The convex conductor 201 is formed of copper, for example, and is integrally provided with a flat cuboid shaped main body, and a flat cuboid shaped convex portion projecting from one main surface of the main body with a diameter smaller than the main body. A flat main surface side of the main body of the convex conductor 201 is jointed electrically and mechanically to the electrode of the semiconductor element 12 with a solder sheet.

A convex conductor 202 (second convex conductor) for positioning is jointed on the electrode of the surface of the semiconductor element 22, via a connecting body 104 (fourth connecting body) such as a rectangular solder sheet. The convex conductor 202 is formed of copper, for example, and is integrally provided with a flat cuboid shaped main body, and a flat cuboid shaped convex portion projecting from one main surface of the main body with a diameter smaller than the main body. A flat main surface side of the main body of the convex conductor 202 is jointed electrically and mechanically to the electrode of the semiconductor element 22 with a solder sheet. In addition, the convex conductor 201 and the convex conductor 202 are composed not only by separate bodies, but may be configured such that the two main bodies are formed integrally, and the two convex portions are provided on the common main bodies.

The semiconductor element 32 is arranged in parallel with the joint surface 31a of the conductor 31, and the electrode of the back surface is jointed to the joint surface 31a of the conductor 31 with a connecting body 106 (sixth connecting body), such as a rectangular solder sheet. The semiconductor element 42 is arranged in parallel with the joint surface 31a of the conductor 31, and is further arranged side by side with the semiconductor element 32 at an interval in the longitudinal direction of the conductor 31. In the semiconductor element 42, the electrode of the back surface is jointed to the joint surface 31a of the conductor 31 with a connecting body 107 (seventh connecting body), such as a rectangular solder sheet.

The semiconductor element 32 and the semiconductor element 42 are arranged in parallel with the joint surface 31a of the conductor 31, and vertical to the bottom surface 31b of the conductor 31. In addition, a connecting body 110 (tenth connecting body) such as a rectangular solder sheet is provided on the joint surface 31a of the conductor 31, and is located side by side at the side of the semiconductor element 32.

A convex conductor 203 (third convex conductor) for positioning is jointed on the electrode of the surface of the semiconductor element 32, via a connecting body 108 (eighth connecting body) such as a rectangular solder sheet. The convex conductor 203 is formed of copper, for example, and is integrally provided with a flat cuboid shaped main body, and a flat cuboid shaped convex portion projecting from one main surface of the main body with a diameter smaller than the main body. A flat main surface side of the main body of the convex conductor 203 is jointed electrically and mechanically to the electrode of the semiconductor element 32 with a solder sheet.

A convex conductor 204 (fourth convex conductor) for positioning is jointed on the electrode of the surface of the semiconductor element 42, via a connecting body 109 (ninth connecting body) such as a rectangular solder sheet. The convex conductor 204 is formed of copper, for example, and is integrally provided with a flat cuboid shaped main body, and a flat cuboid shaped convex portion projecting from one main surface of the main body with a diameter smaller than the main body. A flat main surface side of the main body of the convex conductor 204 is jointed electrically and mechanically to the electrode of the semiconductor element 42 with a solder sheet. In addition, the convex conductor 203 and the convex conductor 204 are composed not only by separate bodies, but may be configured such that the two main bodies are formed integrally, and the two convex portions are provided on the common main bodies.

The semiconductor module 1 includes the power terminal 401 (first power terminal), the power terminal 402 (second power terminal), the power terminal 403 (third power terminal), the five signal terminals 404 (first signal terminals) continuing to the power terminal 401, for example, the five signal terminals 405 (second signal terminals) continuing to the power terminal 402, for example, which are respectively composed by a lead frame LF made of a conductive metal plate shown in FIG. 14. In addition, the semiconductor module shown in FIG. 13 has the lead frame with the similar configuration.

A base end portion of the power terminal 401 is jointed to the joint surface 21a of the conductor 21 with a solder sheet. The power terminal 401 projects from an end of the conductor 11 in the longitudinal direction toward the outside of the semiconductor module 1. A base end portion of the power terminal 402 is jointed to the joint surface 11a of the conductor 11 with a solder sheet. The power terminal 402 projects from an end of the conductor 31 in the longitudinal direction. A base end portion of the power conductor 403 is jointed to the joint surface 31a of the conductor 31 with a solder sheet. The power terminal 403 projects from an end of the conductor 31 in the longitudinal direction toward the outside of the semiconductor module 1.

As shown in FIG. 14, the lead frame LF has a connection portion 50. In the connection portion 50, an opening 301 (first opening), an opening 302 (second opening), an opening 303 (third opening), and an opening 304 (fourth opening) which are for positioning and with a rectangular shape are formed side by side. The opening 301 is formed with a size so that the convex portion of the convex conductor 201 can be fitted therein, and smaller than the main body of the convex conductor 201. The opening 302 is formed with a size so that the convex portion of the convex conductor 202 can be fitted therein, and smaller than the main body of the convex conductor 202. Similarly, the opening 303 is formed with a size so that the convex portion of the convex conductor 203 can be fitted therein, and smaller than the main body of the convex conductor 203. The opening 304 is formed with a size so that the convex portion of the convex conductor 204 can be fitted therein, and smaller than the main body of the convex conductor 204.

On the surface of the connection portion 50 at the conductor 21 side, a shallow rectangular recess is formed over an area containing the opening 301 and the opening 302. The connection portion 50 and the power terminal 402 are jointed to the convex conductor 201 and the convex conductor 202, in the state that the convex portions of the convex conductor 201 and the convex conductor 202 are respectively engaged with the opening 301, the opening 302. The connection portion 50, and the convex portions of the convex conductor 201 and the convex conductor 202 are jointed electrically and mechanically to the joint surface 21a of the conductor 21 with a connecting body 111 (eleventh connecting body) such as a rectangular solder sheet arranged in the recess of the connection portion 50. That is, the connection portion 50, the convex conductor 201, the convex conductor 202, and the conductor 21 are mutually jointed with the solder sheet.

On the surface of the connection portion 50 at the conductor 41 side, a shallow rectangular recess is formed over an area containing the opening 303 and the opening 304. The connection portion 50 and the power terminal 404 are jointed to the convex conductor 203 and the convex conductor 204, in the state that the convex portions of the convex conductor 203 and the convex conductor 204 are respectively engaged with the opening 303, the opening 304. The connection portion 50, and the convex portions of the convex conductor 203 and the convex conductor 204 are jointed electrically and mechanically to the joint surface 41a of the conductor 41 with a connecting body 112 (twelfth connecting body) such as a rectangular solder sheet arranged in the recess of the connection portion 50. That is, the connection portion 50, the convex conductor 203, the convex conductor 204, and the conductor 41 are mutually jointed with the solder sheet.

The electrode of the semiconductor element 12 is electrically connected to the joint surface 21a of the conductor 21 via the convex conductor 201. The electrode of the semiconductor element 22 is electrically connected to the joint surface 21a of the conductor 21 via the convex conductor 202. The semiconductor element 12 and the semiconductor element 22 are sandwiched between the conductor 11 and the conductor 21, and are arranged in parallel with the joint surfaces and vertically to the bottom surfaces of the conductor 11 and the conductor 21.

The electrode of the semiconductor element 32 is electrically connected to the joint surface 41a of the conductor 41 via the convex conductor 203. The electrode of the semiconductor element 42 is electrically connected to the joint surface 41a of the conductor 41 via the convex conductor 204. The semiconductor element 32 and the semiconductor element 42 are sandwiched between the conductor 31 and the conductor 41, and are arranged in parallel with the joint surfaces and vertically to the bottom surfaces of the conductor 31 and the conductor 41.

The signal terminals 404 and the signal terminals 405 project from the semiconductor module 1, and extend in parallel with the joint surface 11a of the conductor 11 and the joint surface 31a of the conductor 31. The base end of the signal terminal 404 is connected to the control terminal of the semiconductor element 12 by a bonding wire (lead wire, such as aluminium wire), for example. The base end of the signal terminal 405 is connected to the control terminal of the semiconductor element 32 by a bonding wire, for example.

As shown in FIG. 5 to FIG. 10, the semiconductor module 1 is provided with a mold resin 60 as an insulator, which has coated the above-described constituent members. The mold resin 60 is formed in a cuboid shape, for example. The mold resin 60 includes a flat bottom surface 61 which extends vertically to the semiconductor element 12 to the semiconductor element 42, and from which the bottom surface 11b of the conductor 11 and the bottom surface 21b of the conductor 21 are exposed, a flat side surface 62 (first side surface) which extends vertically to the bottom surface 61, a side surface 63 (second side surface) which extends vertically to the bottom surface 61 and faces the side surface 62 in parallel, a ceiling surface 64 which is located between the side surface 62 and the side surface 63, and faces the bottom surface 61, an end surface 65 (first end surface) which extends while crossing with one ends of the bottom surface 61 and the side surface 62, the side surface 63, and an end surface 66 (second end surface) which extends while crossing with the other ends of the bottom surface 61 and the side surface 62, the side surface 63. In the embodiment, the side surface 62 and the side surface 63 are located in parallel with the joint surface 11a of the conductor 11 and the joint surface 21a of the conductor 21. In addition, the semiconductor module shown in FIG. 13 is configured in the same way.

As shown in FIG. 5 and FIG. 6, the mold resin 60 has a parting line 67 which is formed at the time of being demolded from a forming die. The parting line 67 is formed over the end surface 65, the ceiling surface 64, the end surface 66 of the mold resin 60, and extends in parallel with the side surface 62 and the side surface 63. The parting line 67 is located while being displaced toward the surface side 62 from the center of the mold resin 60 in the short direction, and is located in a plane containing the connection portion 50 of the lead frame, the base end portions (main bodies) of the power terminal 401 to the power terminal 403.

In the ceiling surface 64 of the mold resin 60, a portion between the parting line 67 and the side surface 62 extends slightly tiltedly to the bottom surface 61 side, from the parting line 67 toward the side surface 62. A portion between the parting line 67 and the side surface 63 extends slightly tiltedly to the bottom surface 61 side, from the parting line 67 toward the side surface 63.

In each of the end surfaces of the mold resin 60, a portion between the parting line 67 and the side surface 62 extends slightly tiltedly to the other end surface side, from the parting line 67 toward the side surface 62. A portion between the parting line 67 and the side surface 63 extends slightly tiltedly to the other end surface side, from the parting line 67 toward the side surface 63.

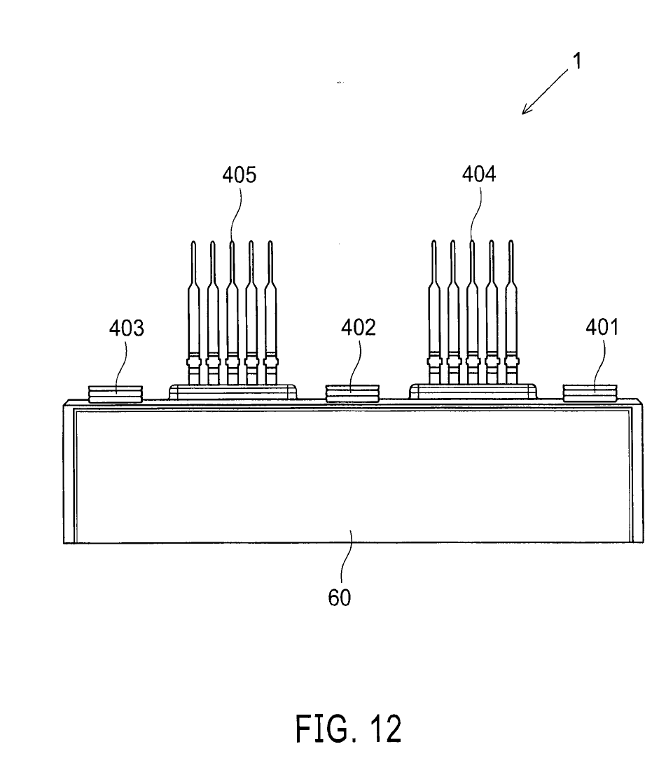

As shown in FIG. 5, FIGS. 8-10, FIG. 12, each of the power terminal 401 to the power terminal 403 projects from one end surface of the mold resin 60 to the outside of the mold resin 60 in the short direction at the position of the parting line 67. Each of the power terminal 401 to the power terminal 403 has a main body which is located in parallel with the side surface 62, and a contact portion which is bent in parallel with the ceiling surface 64. A hole for screwing is provided in the contact portion, for example. The contact portion may be provided with a penetration portion for welding, for example.

In the signal terminal 404 and the signal terminal 405, each of the five signal terminals is formed in a slender bar shape, and projects upward from the ceiling surface 64 of the mold resin 60 at the position of the parting line 67. The five signal terminals extend in parallel with each other. Each of the signal terminals has a base end portion which extends from the position of the parting line 67 in parallel with the side surface 62 on the ceiling surface 64, a bending portion which is bent at two places separated from the base end portion in the longitudinal direction, and a connection end portion which extends from the bending portion. The connection end portion is located at the center of the mold resin 60 in a thickness direction H.

As shown in FIG. 11, the five signal terminals of the signal terminal 404 and the five signal terminals of the signal terminal 405 are horizontally symmetrically arranged with respect to a center line L located at the center of the mold resin 60 in the longitudinal direction. A conductive film not shown is formed on at least the outer surface of the connection end portion of the signal terminal.

The bottom surface 61 of the semiconductor module 1 contacts with a heat receiving portion of the cooler 2 via an insulating portion of the cooler 2 (shown in FIG. 3, FIG. 6). Heat generated in the semiconductor module 1 is cooled by the heat receiving portion of the cooler 2. Specifically, the heats generated in the semiconductor element 12 to the semiconductor element 42 can be radiated by the cooler 2 via the conductor 11 to the conductor 41. Each of the contact portions of the power terminal 401 to the power terminal 403 of the semiconductor module 1 contacts with a connecting terminal of an external wiring and is electrically connected thereto. The signal terminal 404 and the signal terminal 405 of the semiconductor module 1 project upward.

In the semiconductor module 1, the semiconductor module 1A, the semiconductor module 1B which are arranged in a row (shown in FIG. 2), the two adjacent semiconductor modules may be arranged in the state that the side surfaces of the mold resins 60 are adjacent and opposite to each other, or are engaged with each other. Out of the two adjacent semiconductor modules, one may be arranged in the direction reversed by 180 degrees with respect to the other one. In what directions the semiconductor modules may be arranged, they are surely engaged with connecting terminals of a bus bar, by changing the length and bending direction of the power terminal 401 to the power terminal 403.

According to the semiconductor module 1 of the embodiment, since the four conductors (the conductor 11 to the conductor 41) can be housed in one module, the semiconductor module 1 has higher heat radiation property compared with a semiconductor module in which two conductors are housed in one module, for example, and thereby it is possible to increase the power which is dealt in one module.

Further, when it is tried to obtain the same power conversion efficiency, using a plurality of the semiconductor modules of the embodiment, and using a plurality of semiconductor modules in each of which two conductors are housed in one module, the case to use the semiconductor modules of the embodiment uses a smaller number of the semiconductor modules. That is, the number of the external wirings connecting between the semiconductor modules becomes smaller. Accordingly, the semiconductor modules of the embodiment can be arranged more densely, and when the semiconductor modules of the embodiment are used, it is possible to obtain a semiconductor power converter with a smaller size.

For this reason, according to the embodiment, it is possible to achieve a miniaturization and an improvement in reliability, and a semiconductor module can be obtained as a semiconductor device which can be installed in a row densely.

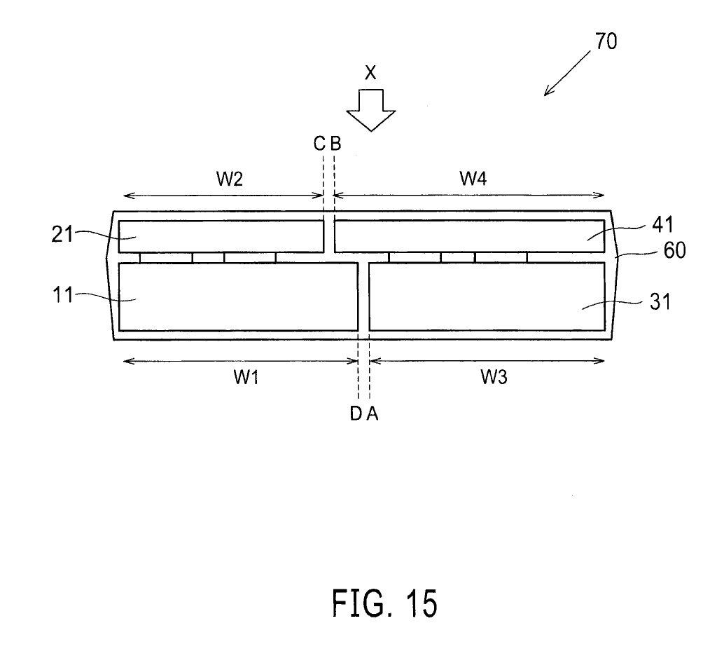

A semiconductor device according to a second embodiment will be described with reference to the drawings. FIG. 15 is a sectional view showing a semiconductor module as a semiconductor device. The fundamental structure of the semiconductor module of the embodiment is the same as the semiconductor module described in the first embodiment. In the second embodiment described below, the same symbols are given to the same portions as in the above-described first embodiment, the detailed description thereof is omitted, and the different portions will be mainly described in detail.

As shown in FIG. 15, in a semiconductor module 70 as a semiconductor device, a plane A of the conductor 31 which is adjacent to the conductor 11, and a plane B of the conductor 41 which is adjacent to the conductor 21 are not on the same plane. A plane C of the conductor 21 which is adjacent to the conductor 41, and a plane D of the conductor 11 which is adjacent to the conductor 31 are not on the same plane.

In the semiconductor module 70, a width W1 of the conductor 11 in the longitudinal direction and a width W2 of the conductor 21 in the longitudinal direction are different. A width W3 of the conductor 31 in the longitudinal direction and a width W4 of the conductor 41 are different.

In addition, the semiconductor module 70 may have a configuration in which at least a portion of the conductor 11 and at least a portion of the conductor 41 are overlapped with each other, when seen from a direction X vertical to the semiconductor element 12.

In the semiconductor module 1 of the first embodiment, in portions respectively between the conductor 11 and the conductor 21, and the conductor 31 and the conductor 41 almost only the mold resin exists, and when copper is used as the material of the conductor, since the strength of the mold resin is lower than the strength of the conductor, when a mechanical load is applied, there is a possibility that a damage occurs at this portion.

On the other hand, in the semiconductor module 70, the shapes or arrangements of the conductor 11 to the conductor 41 are changed so that a portion between the conductor 11 and the conductor 21, and a portion between the conductor 31 and the conductor 41 do not overlap with each other, when seen from the direction X vertical to the semiconductor element 12, and thereby the strength of the semiconductor module can be ensured.

Between the conductor 11 and the conductor 31, and between the conductor 21 and the conductor 41, it is necessary to provide a prescribed distance for ensuring insulation. The semiconductor module is required to reduce a transient thermal resistance. Accordingly, as the semiconductor module, a structure in which the sizes of the conductor 11 to the conductor 41 become maximum, while ensuring insulation property is desirable.

The semiconductor module is configured to have a structure of the embodiment, and thereby a length of a route through which current flows, especially, a current route at the battery N side (low potential side power source side) can be shortened. By this means, the difference between the current routes of the battery P side and the battery N side becomes small, and thereby it is possible to achieve the improvement of the electrical properties.

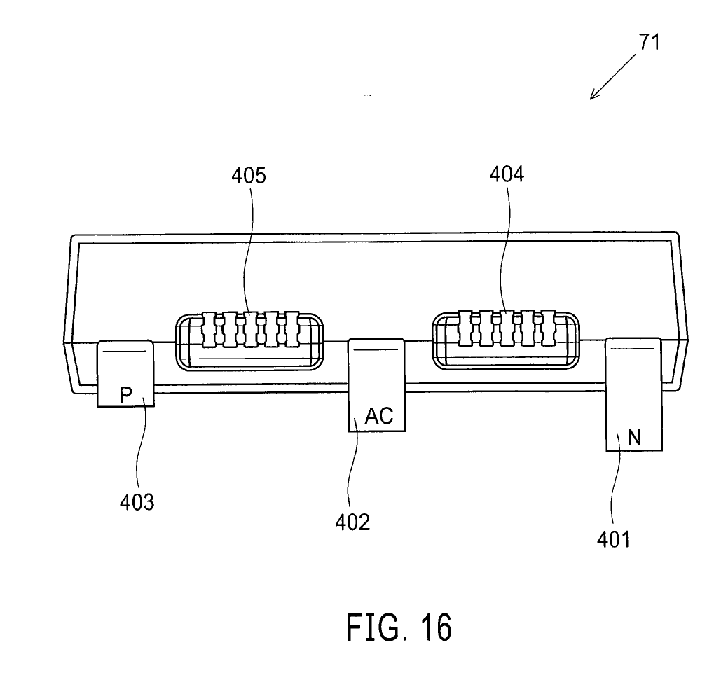

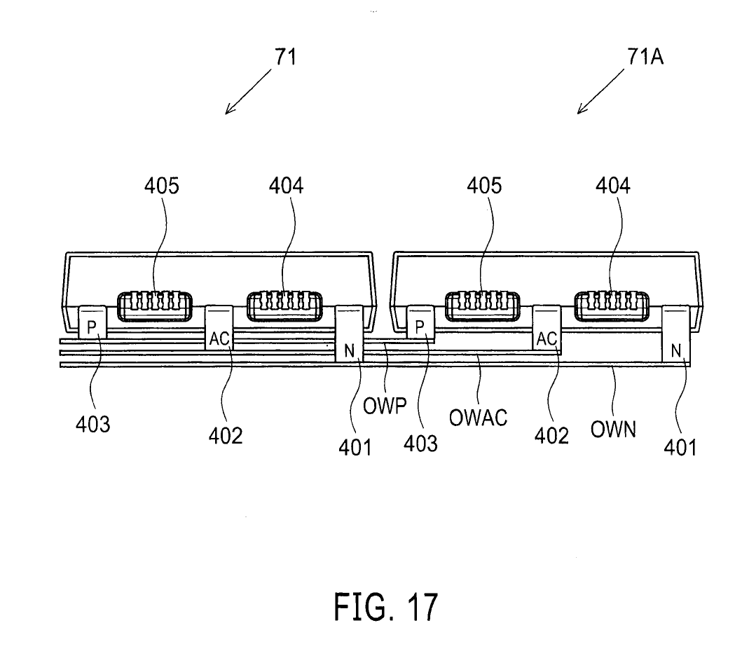

A semiconductor device according to a third embodiment will be described with reference to the drawings. FIG. 16 is a perspective view showing a semiconductor module as a semiconductor device. FIG. 17 is a diagram showing a connection example of the semiconductor modules. The fundamental structure of the semiconductor module of the embodiment is the same as the semiconductor module described in the first embodiment. In the third embodiment described below, the same symbols are given to the same portions as in the above-described first embodiment, second embodiment, the detailed description thereof is omitted, and the different portions will be mainly described in detail.

The point that a semiconductor module 71 as a semiconductor module according to the embodiment is different from the semiconductor module of the first embodiment, the second embodiment is that the lengths of the power terminal 401 to the power terminal 403 are different.

As shown in FIG. 16, in the semiconductor module 71, the power terminal 403 to be connected to the battery P has an extending portion shorter than that of the power terminal 402. The power terminal 402 (AC terminal) to be connected to the motor M has an extending portion shorter than that of the power terminal 401. The power terminal 401 to be connected to the battery N has an extending portion longer than those of the power terminal 402 and the power terminal 403.

Each of the power terminal 401 to the power terminal 403 is electrically connected to an external winding from the battery or an external winding to the motor M. For example, since a current used in an inverter for a hybrid vehicle and an electric vehicle becomes not less than 100 A, an external wiring of a copper plate with a thickness of not less than 1 mm is generally used. In such a situation, it is difficult to form complicated wirings.

As shown in FIG. 17, a semiconductor module 71A having the same configuration as the semiconductor module 71 is arranged in parallel with the semiconductor module 71. For this reason, external windings to be connected respectively to the three power terminals of the semiconductor module 71 are different from external windings to be connected respectively to the three power terminals of the semiconductor module 71A.

Specifically, an external wiring OWP to be connected to the battery P and the power terminals 403 is arranged adjacent to the semiconductor module 71 and the semiconductor module 71A. An external wiring OWAC to be connected to the motor M and the power terminals 402 is arranged at the outside and in parallel with the external wiring OWP. An external wiring OWN to be connected to the battery N and the power terminals 401 is arranged at the outside and in parallel with the external wiring OWAC.

The semiconductor module 71 and the semiconductor module 71A are made to have a structure like the embodiment, and thereby it is possible to simply connect the semiconductor modules with the external wirings formed in a straight line.

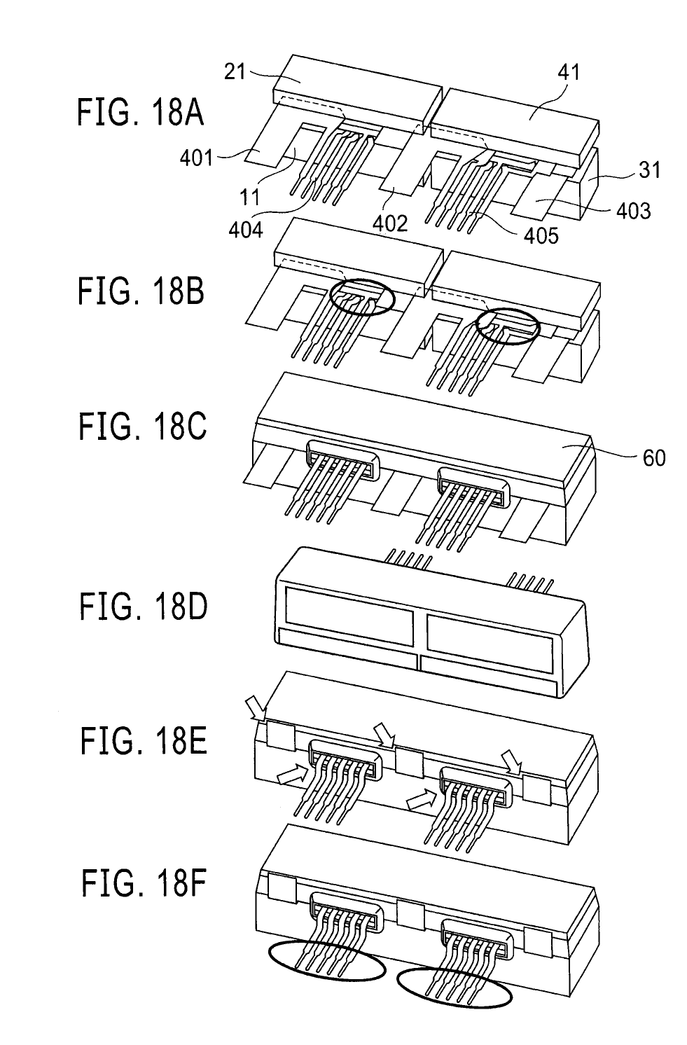

A method of fabricating a semiconductor device as a semiconductor device according to a third embodiment will be described with reference to the drawings. FIG. 18A to FIG. 18F are views for explaining a method of fabricating a semiconductor module as a semiconductor device. A semiconductor module fabricated by the embodiment is the same as the semiconductor module 1 described in the first embodiment.

As shown in FIG. 18A, the respective components and solders are provided between the conductor 11 to the conductor 41. And the solders are melted by applying heat to the solders, and thereby the respective components are jointed to the conductor 11 to the conductor 41.

Specifically, the connecting body 101 and the connecting body 102 are provided on the joint surface 11a of the conductor 11. The semiconductor element 12 is provided on the connecting body 101, so that the first electrode contacts with the connecting body 101. The semiconductor element 22 is provided on the connecting body 102, so that the first electrode contacts with the connecting body 102. The connecting body 103 is provided on the second electrode of the semiconductor element 12. The connecting body 104 is provided on the second electrode of the semiconductor element 22. The connecting body 105 is provided on the joint surface 11a of the conductor 11. The convex conductor 201 is provided on the connecting body 103. The convex conductor 202 is provided on the connecting body 104.

The connecting body 106 and the connecting body 107 are provided on the joint surface 31a of the conductor 31. The semiconductor element 32 is provided on the connecting body 106, so that the first electrode contacts with the connecting body 106. The semiconductor element 42 is provided on the connecting body 107, so that the first electrode contacts with the connecting body 107. The connecting body 108 is provided on the second electrode of the semiconductor element 32. The connecting body 109 is provided on the second electrode of the semiconductor element 42. The connecting body 110 is provided on the joint surface 31a of the conductor 31. The convex conductor 203 is provided on the connecting body 108. The convex conductor 204 is provided on the connecting body 109.

The lead frame LF is fitted such that the opening 301 is fitted to the convex portion of the convex conductor 201, the opening 302 is fitted to the convex portion of the convex conductor 202, the opening 303 is fitted to the convex portion of the convex conductor 203, the opening 304 is fitted to the convex portion of the convex conductor 204. The power terminal 402 is provided on the connecting body 105. The power terminal 403 is provided on the connecting body 110.

On the connection portion 50 of the lead frame LF, the connecting body 111 is provided on the convex portions of the convex conductor 201 and the convex conductor 202, The conductor 21 is provided on the connecting body 111, so that the joint surface 21a becomes opposite to the joint surface 11a of the first conductor 11. On the connection portion 50 of the lead frame LF, the connecting body 112 is provided on the convex portions of the convex conductor 203 and the convex conductor 204. The conductor 41 is provided on the connecting body 112, so that the joint surface 41a becomes opposite to the joint surface 31a of the conductor 31.

The connecting body 101 to the connecting body 112 are melted together and solidified, and thereby the conductor 11, the semiconductor element 12 and the semiconductor element 22, the convex conductor 201 and the convex conductor 202, the power terminal 401 and the power terminal 402, the connection portion 50, the conductor 21 are jointed. Similarly, the conductor 31, the semiconductor element 32 and the semiconductor element 42, the convex conductor 203 and the convex conductor 204, the power terminal 402 and the power terminal 403, the connection portion 50, the conductor 41 are jointed.

As shown in FIG. 18B, the lead frame LF, and the semiconductor element 12 and the semiconductor element 32 are connected by wire bonding. Specifically, the control electrode of the semiconductor element 12 and the signal terminal 404 are connected by a lead wire, and the control electrode of the semiconductor element 32 and the signal terminal 405 are connected by a lead wire.

As sown in FIG. 18C, the whole is sealed with the mold resin 60. Specifically, the base end portions of the power terminal 401 to the power terminal 403, the base end portions of the signal terminal 404 to the signal terminal 405, the semiconductor element 12 to the semiconductor element 42, and the other whole constituent members are covered with the mold resin 60.

As sown in FIG. 18D, the bottom surface 61 of the mold resin 60 is cut, to make the conductor 11 to the conductor 41 to be exposed. Specifically, while the connection portion 50, the power terminal 401 to the power terminal 403, the signal terminal 404 and the signal terminal 405 of the lead frame LF are left, and the other portions of the lead frame LF are cut. The mold resin 60 is ground, to form the bottom surface which extends in the direction vertical to the semiconductor element 12 to the semiconductor element 42, and from which the bottom surface 11b of the conductor 11, the bottom surface 21b of the conductor 21, the bottom surface 31b of the conductor 31, and the bottom surface 41b of the conductor 41 are exposed.

As sown in FIG. 18E, leads of the power terminal 401 to the power terminal 403, the signal terminal 404 and the signal terminal 405 are cut, and are bent to perform forming.

The tips of the signal terminal 404 and the signal terminal 405 are plated, in order to improve the solder wettability. With the processes described above, the semiconductor module 1 is completed.

In addition, in the fabrication process (refer to FIG. 18D) of the semiconductor module 1, the bottom surface 61 of the mold resin 60 is ground, and thereby is flattened. At this time, the side surface 62 and the side surface 63 of the mold resin 60 are formed flat and in parallel with each other (refer to FIG. 5 and FIG. 6). For this reason, the semiconductor module 1 can be tightly held, by sandwiching and pressurizing the side surface 62 and the side surface 63 by a damper. The bottom surface 61 is ground in the state that the semiconductor module 1 is tightly held, and thereby it is possible to form the bottom surface 61 with high flatness. By increasing the flatness of the bottom surface 61 of the mold resin 60, the bottom surface 61 of the semiconductor module 1 is made to firmly adhere to the heat receiving surface of the cooler 2, and the heat resistance can be reduced. As a result, it is possible to improve the cooling efficiency of the semiconductor module 1. In addition the conductor 11 to the conductor 41 can be made smaller.

The bottom surface 61 of the semiconductor module 1 is ground in the state that the semiconductor module 1 is tightly grasped from the both side of the side surface 62 and the side surface 63, and thereby separation between the mold resin 60, and the conductor 11 to the conductor 41 caused by grinding can be prevented. For this reason, it is possible to improve the reliability of the semiconductor module.

It is possible to provide a power converter with miniaturization and high reliability, by densely arranging the semiconductor modules described in the embodiments in a row.

While certain embodiments have been described, these embodiments have been presented by way of example only, and are not intend to limit the scope of the inventions. Indeed, the novel embodiments described herein may be embodied in a variety of the other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first semiconductor element provided between a first conductor and a second conductor, having a first electrode connected to the first conductor, a second electrode connected to the second conductor, and a control electrode connected to a first signal terminal;
a second semiconductor element provided between the first conductor and the second conductor, having a first electrode connected to the first conductor, and a second electrode connected to the second conductor;
a third semiconductor element provided between a third conductor and a fourth conductor, having a first electrode connected to the third conductor, a second electrode connected to the fourth conductor, and a control electrode connected to a second signal terminal;
a fourth semiconductor element provided between the third conductor and the fourth conductor, having a first electrode connected to the third conductor, and a second electrode connected to the fourth conductor;
a first power terminal having one end connected to the second conductor and the other end extending more outward than the second conductor;
a second power terminal which connects the first conductor and the fourth conductor and extends more outward than the first conductor and the fourth conductor; and
a third power terminal having one end connected to the third conductor and the other end extending more outward than the third conductor.

2. The semiconductor device according to claim 1, further comprising:
an insulator provided to cover base end portions of the first to third power terminals, base end portions of the first and second signal terminals, the first to fourth conductors, and the first to fourth semiconductor elements.

3. The semiconductor device according to claim 2, wherein the first to third power terminals are bent in parallel with one side surface of the insulator.

4. The semiconductor device according to claim 2, wherein the insulator is exposed on one side surfaces of the first to the fourth conductors, and contacts with a cooler.

5. The semiconductor device according to claim 2, wherein the insulator is composed of mold resin.

6. The semiconductor device according to claim 1, wherein a signal outputted from the second power terminal is inputted to a motor.

7. The semiconductor device according to claim 1, wherein a low potential side power source is supplied to the first power terminal, and a high potential side power source is supplied to third power terminal.

8. The semiconductor device according to claim 2, wherein the insulator is divided by a parting line.

9. The semiconductor device according to claim 1, wherein one side surface of the third conductor adjacent to a plane opposite to the first conductor, and one side surface of the fourth conductor adjacent to a plane opposite to the second conductor are not on the same plane.

10. The semiconductor device according to claim 1, wherein one side surface of the second conductor adjacent to a plane opposite to the fourth conductor, and one side surface of the first conductor adjacent to a plane opposite to the third conductor are not on the same plane.

11. The semiconductor device according to claim 1, wherein a width of the first conductor in a longitudinal direction and a width of the second conductor in a longitudinal direction are different.

12. The semiconductor device according to claim 1, wherein a width of the third conductor in a longitudinal direction and a width of the fourth conductor in a longitudinal direction are different.

13. The semiconductor device according to claim 1, wherein the first conductor and the fourth conductor have each a plate-like shape, and are arranged so as to overlap with each other when seen from a direction vertical to a plate-like plane.

14. The semiconductor device according to claim 1, wherein the first semiconductor element and the third semiconductor element are each an IGBT, and the second semiconductor element and the fourth semiconductor element are each a diode.

15. The semiconductor device according to claim 1, wherein copper (Cu) or copper alloy is used as the first to fourth conductors.

16. The semiconductor device according to claim 1, wherein the semiconductor device is a power converter to perform conversion from DC power to AC power.

17. The semiconductor device according to claim 1, wherein
the first power terminal is provided between the second conductor and the second electrode of the second semiconductor element; and
the third power terminal is provided between the third conductor and the first electrode of the fourth semiconductor element.

18. The semiconductor device according to claim 1, wherein lengths of the first to third power terminals are different.

19. A method of fabricating a semiconductor device, comprising:
providing a first connecting body and a second connecting body on a first conductor;
providing a first semiconductor element having a first electrode and a control electrode on a surface and a second electrode on a back surface, so that the second electrode of the first semiconductor element is on the first connecting body;
providing a second semiconductor element having a first electrode on a surface and a second electrode on a back surface, so that the second electrode of the second semiconductor element is on the second connecting body;
providing a third connecting body on the first electrode of the first semiconductor element, and providing a fourth connecting body on the first electrode of the second semiconductor element;
providing a fifth connecting body on the first conductor;
providing a first convex conductor on the third connecting body, and providing a second convex conductor on the fourth connecting body;
providing a sixth connecting body and a seventh connecting body on a third conductor;
providing a third semiconductor element having a first electrode and a control electrode on a surface and a second electrode on a back surface, so that the second electrode of the third semiconductor element is on the sixth connecting body;
providing a fourth semiconductor element having a first electrode on a surface and a second electrode on a back surface, so that the second electrode of the fourth semiconductor element is on the sixth connecting body;
providing an eighth connecting body on the first electrode of the third semiconductor element, and providing a ninth connecting body on the first electrode of the fourth semiconductor element;
providing a tenth connecting body on the third conductor;
providing a third convex conductor on the eighth connecting body, and loading a fourth convex conductor on the ninth connecting body;
providing a lead frame having a plate-like connection portion with first to fourth openings, first to third power terminals, first and second signal terminals, such that the first opening is fitted to a convex portion of the first convex conductor, the second opening is put on a convex portion of the second convex conductor, the third opening is fitted to a convex portion of the third convex conductor, the fourth opening is fitted to a convex portion of the fourth convex conductor; providing the second power terminal on the fifth connecting body;
providing the third power terminal on the tenth connecting body;
providing an eleventh connecting body on the connection portion of the lead frame, so as to contact with the convex portions of the first convex conductor and the second convex conductor;
providing the second conductor on the eleventh connecting body;
providing a twelfth connecting body on the connection portion of the lead frame, so as to contact with the convex portions of the third convex conductor and the fourth convex conductor;
providing the fourth conductor on the twelfth connecting body; and
solidifying the first to twelfth connecting bodies after collective melting, to joint the first conductor, the first and second semiconductor elements, the first and second convex conductors, the first and second power terminals, the connection portion, the second conductor, and to joint the third conductor, the third and fourth semiconductor elements, the third and fourth convex conductors, the second and third power terminals, the connection portion, the fourth conductor.

20. The method of fabricating a semiconductor device according to claim 19, further comprising:
connecting a control electrode of the first semiconductor element and the first signal terminal with a conductive wire;
connecting a control electrode of the third semiconductor element and the second signal terminal with a conductive wire;
covering base end portions of the first to third power terminals, base end portions of the first and second signal terminals, the first to fourth semiconductor elements with an insulator;
cutting the lead frame so that the connection portion, the first to third power terminals, the first and second signal terminals of the lead frame, are remained;
grinding the insulator, to expose one side surfaces of the first to fourth conductors in directions vertical to the first to fourth semiconductor elements; and
forming after bending the first to third power terminals, and the first and second signal terminals.
